(19) United States
(12) Patent Application Publication
(10) Pub. No.: US 2026/0026310 A1
(43) Pub. Date: Jan. 22, 2026

(54) METHODS AND SYSTEMS FOR HYBRID BONDING LARGE SUBSTRATES

(71) Applicant: Adeia Semiconductor Bonding Technologies Inc., San Jose, CA (US)

(72) Inventors: Cyprian Emeka Uzoh, San Jose, CA (US); Belgacem Haba, Saratoga, CA (US); Rajesh Katkar, Milpitas, CA (US)

(21) Appl. No.: 18/985,685

(22) Filed: Dec. 18, 2024

Related U.S. Application Data
(60) Provisional application No. 63/673,524, filed on Jul. 19, 2024.

(51) Int. Cl. H01L 21/66; H01L 23/00

(52) U.S. Cl. CPC H01L 22/12; H01L 24/74; H01L 24/80; H01L 24/98; H01L 2224/74; H01L 2224/80201; H01L 2224/98

(57) ABSTRACT

Method and systems for bonding and/or debonding substrates are disclosed. A method comprises positioning a first surface of a first substrate directly opposite to and at a distance from a surface of a second substrate. The method further comprises applying a first pressure over a first portion of a second surface of the first substrate via pressurized gas to contact a first portion of the first surface of the first substrate to a first portion of the first surface of the second substrate, and applying a second pressure via pressurized gas in a direction opposite a propagation direction of a bonding wave front between the first substrate and the second substrate to control the bonding wave front.

### CROSS-REFERENCE TO RELATED APPLICATION

This application claims the benefit of U.S. Provisional Patent Application No. 63/673,524, filed Jul. 19, 2024, which is hereby incorporated by reference herein in its entirety.

### FIELD

The present disclosure relates to bonding of substrates, and in particular, systems and methods of hybrid bonding of large substrates.

### BACKGROUND

Hybrid bonding with larger die sizes is more challenging and have lower yields than hybrid boding with smaller die sizes. It may be preferred to bond wafer to wafer (W2W) or panel to panel (P2P) as opposed to die to wafer (D2W) methods. Accordingly, there exists a need for improved methods and apparatuses for hybrid bonding larger die sizes (e.g., wafer to wafer, die to wafer).

### SUMMARY

Embodiments herein provide for systems and methods of bonding substrates or large substrates. Advantageously, the systems and methods enable void free bonding of large substrates or reduction of voids in bonding large substrates. The system and methods may also enable in situ rework of bonding large substrates.

A first general aspect includes a method for bonding substrates comprising positioning a first surface of a first substrate directly opposite to and at a distance from a surface of a second substrate, applying a first pressure over a first portion of a second surface of the first substrate via pressurized gas to contact a first portion of the first surface of the first substrate to a first portion of the first surface of the second substrate, and applying a second pressure via pressurized gas in a direction opposite a propagation direction of a bonding wave front between the first substrate and the second substrate to control the bonding wave front.

Another general aspect includes a method for bonding substrates comprising positioning a first surface of a first substrate directly opposite to and at a distance from a surface of a second substrate, the first substrate smaller than second substrate, applying a first pressure over a first portion of a second surface of the first substrate via pressurized gas to contact a first portion of the first surface of the first substrate to a first portion of the first surface of the second substrate, and applying a second pressure via pressurized gas in a direction opposite a propagation direction of a bonding wave front between the first substrate and the second substrate to control the bonding wave front.

In some embodiments, the method of claim further comprises applying the first pressure while moving radially outwards and around the first portion of the second surface of the first substrate, and concurrently applying the second pressure while moving radially outwards from the first portion of the second surface of the first substrate.

The applied pressures may be regulated in different ways. In some embodiments, the method further comprises detecting a defect in a bonded portion of the substrates using an infrared camera, and reducing the applied first pressure and increasing the applied second pressure on a current position of a portion of the bonded wafers. In some embodiments, reducing the applied first pressure comprises moving the applied first pressure away from the first substrate. In some embodiments, reducing the applied first pressure comprises moving the applied first pressure inwards towards a previously bonded portion of the substrates. In some embodiments, reducing the applied first pressure comprises closing a valve to prevent the first pressure from being applied. In some embodiments, increasing the applied second pressure comprises moving the applied second pressure inwards towards a previously bonded portion of the substrates. In some embodiments, the defect is a particle, and the method further comprises maintaining or increasing the second pressure at a position of the defect to remove the particle from between the substrates.

The substrates may be positioned in different ways. In some embodiments, positioning the first surface of the first substrate directly opposite to and at the distance from the first surface of the second substrate comprises balancing the first pressure applied downward on top of the first substrate and the second pressure applied upwards on the bottom of the first substrate. In some embodiments, positioning the first surface of the first substrate directly opposite to and at the distance from the first surface of the second substrate comprises lowering the first substrate to the second substrate by a motorized portion of the handling device.

The substrates may have different sizes or diameters. In some embodiments, the first substrate and the second substrate are wafers or dies with size greater than about 10 mm in size. In some embodiments, the first substrate and the second substrate are wafers about 100 mm or greater in diameter. In some embodiments, the first substrate and the second substrate are wafers about 200 mm or greater in diameter. In some embodiments, the first substrate and the second substrate are wafers about 300 mm or greater in diameter. In some embodiments, the second substrate is at least 2 times larger than the first substrate, at least 4 times larger than the first substrate, or at least 10 times larger than the first substrate prior to the bonding operation. In some embodiments, subsequent to the bonding of the first and second substrates, the second substrate may be singulated.

In some embodiments, one or more additional dies may be bonded on the prepared backside of the first substrate. The one or more additional dies may be similar or smaller or larger in size to the first substrate.

The substrates may be aligned in different ways. In some embodiments, the method further comprises picking up the first substrate using an end effector, and aligning the first substrate to the second substrate. In some embodiments, the method further comprises floating the first substrate over the second substrate by balancing the first pressure and the second pressure.

A second general aspect includes a method of debonding substrates, the method comprising applying vacuum on an outward facing surface of the bonded substrates, applying pressurized gas at an edge of the bonded surfaces of the substrates and in a direction parallel to the bonded surfaces of the substrates to initiate debonding of the substrates, and moving the pressurized gas towards a center of the bonded substrates to debond the substrates.

A third general aspect includes an apparatus for bonding and debonding substrates. The apparatus comprises a substrate handling device comprising a holder, such that the substrate handling device capable of applying a vacuum to hold a first substrate against the holder. The apparatus further comprises a bonding initiating device comprising a first motorized stage and a first pressure chamber, such that the bonding initiating device is capable of applying a first pressure to contact a first portion the first substrate to a first portion of a second substrate and moving the first pressure in both lateral and vertical directions. The apparatus further comprises a bonding wave front controller device comprising a second motorized stage and a second pressure chamber, such that the bonding wave front controller device capable of applying a second pressure to control a bonding wave front between the first substrate and the second substrate, and moving the second pressure in a lateral direction.

The apparatus may be capable of detecting defects. In some embodiments, the apparatus further comprises a detection device comprising an infrared camera, such that the detection device capable of detecting defects between the first substrate and the second substrate. In some embodiments, the apparatus further comprises a light scattering detector device, such that the detection device capable of detecting defects or unwanted particles between the first substrate and the second substrate or unwanted particle or particles on the second substrate. In some embodiments, the bonding wave front controller device is capable of applying the second pressure to control the bonding wave front while the detection device captures an image of a bonding wave profile.

### BRIEF DESCRIPTION OF THE DRAWINGS

The above and other objects and advantages of the disclosure will be apparent upon consideration of the following detailed description, taken in conjunction with the accompanying drawings, in which:

FIGS. 1A-1D are illustrative schematic sectional side views of a system at different stages of bonding substrates to illustrate aspects of a method, in accordance with embodiments of the present disclosure;

FIGS. 1E-1H schematically illustrate variations of bonding substrates, in accordance with embodiments of the present disclosure;

FIGS. 2A-2B are illustrative schematic sectional side views of a system at different stages of debonding substrates to illustrate aspects of a method, in accordance with embodiments of the present disclosure;

FIG. 3 is illustrative schematic of a computing device, in accordance with embodiments of the present disclosure; and

FIGS. 4A-4B schematically illustrate hybrid bonding, according to some embodiments.

The figures herein depict various embodiments of the disclosure for purposes of illustration only. It will be appreciated that additional or alternative structures, assemblies, systems, and methods may be implemented within the principles set out by the present disclosure.

### DETAILED DESCRIPTION

As described below, semiconductor substrates herein generally have a “device side,” e.g., the side on which semiconductor device elements are fabricated, such as transistors, resistors, capacitors, and a “backside” that is opposite the device side. The term “active side” should be understood to include a surface of the device side of the substrate and may include the device side surface of the semiconductor substrate and/or a surface of any material layer, device element, or feature formed thereon or extending outwardly therefrom, and/or any openings formed therein. Thus, it should be understood that the material(s) that form the active side may change depending on the stage of device fabrication and assembly. Similarly, the term “non-active side” (opposite the active side) includes the non-active side of the substrate at any stage of device fabrication, including the surfaces of any material layer, any feature formed thereon, or extending outwardly therefrom, and/or any openings formed therein. Thus, the terms “active side” or “non-active side” may include the respective surfaces of the semiconductor substrate at the beginning of device fabrication and any surfaces formed during material removal, e.g., after substrate thinning operations. Depending on the stage of device fabrication or assembly, the terms “active” and “non-active sides” may be used to describe surfaces of material layers or features formed on, in, or through the semiconductor substrate, whether or not the material layers or features are ultimately present in the fabricated or assembled device.

Spatially relative terms are used herein to describe the relationships between elements, such as the relationships between layers and other features described below. Unless the relationship is otherwise defined, terms such as “above,” “over,” “upper,” “upwardly,” “outwardly,” “on,” “below,” “under,” “beneath,” “lower,” and the like are generally made with reference to the drawings. Thus, it should be understood that the spatially relative terms used herein are intended to encompass different orientations of the substrate and, unless otherwise noted, are not limited by the direction of gravity. Unless the relationship is otherwise defined, terms describing the relationships between elements such as “disposed on,” “embedded in,” “coupled to,” “connected by,” “attached to,” “bonded to,” either alone or in combination with a spatially relevant term include both relationships with intervening elements and direct relationships where there are no intervening elements.

Various embodiments disclosed herein include bonded structures in which two or more elements are directly bonded to one another without an intervening adhesive (referred to herein as “direct bonding,” “direct dielectric bonding,” or “directly bonded”). The resultant bonds formed by this technique may be described as “direct bonds” and/or “direct dielectric bonds.” In some embodiments, direct bonding includes the bonding of a single material on the first of the two or more elements and a single material on a second one of the two or more elements, where the single material on the different elements may or may not be the same. For example, bonding a layer of one inorganic dielectric (e.g., silicon oxide) to another layer of the same or different inorganic dielectric. Examples of dielectric materials used in direct bonding include oxides, nitrides, oxynitrides, carbonitrides, and oxycarbonitrides, etc., such as, for example, silicon oxide, silicon nitride, silicon oxynitride, silicon carbonitride, silicon oxycarbonitride, etc. Direct bonding can also include bonding of multiple materials on one element to multiple materials on the other element (e.g., hybrid bonding). As used herein, the term “hybrid bonding” refers to a species of direct bonding having both i) at least one (first) nonconductive feature directly bonded to another (second) nonconductive feature, and ii) at least one (first) conductive feature directly bonded to another (second) conductive feature, without any intervening adhesive. The resultant bonds formed by this technique may be described as “hybrid bonds” and/or “direct hybrid bonds.” In some hybrid bonding embodiments, there are many first conductive features, each directly bonded to a second conductive feature, without any intervening adhesive. In some embodiments, nonconductive features on the first element are directly bonded to nonconductive features of the second element at room temperature without any intervening adhesive, which is followed by bonding of conductive features of the first element directly bonded to conductive features of the second element via annealing at slightly higher temperatures (e.g., >100° C., >200°° C., >250° C., >300° C., etc.).

Direct bonding may include direct dielectric bonding techniques as described herein, and may give rise to direct dielectric bonds. Hybrid bonding may include hybrid bonding techniques as described herein, and may give rise to direct hybrid bonds.

Hybrid bonding methods described herein generally include forming conductive features in the dielectric surfaces of the to-be-bonded substrates, activating the surfaces to open chemical bonds in the dielectric material, and terminating the surfaces with a desired species. In some embodiments, activating the surface may weaken chemical bonds in the dielectric material. Activating and terminating the surfaces with a desired species may include exposing the surfaces to radical species formed in a plasma. In some embodiments, the plasma is formed using a nitrogen-containing gas, e.g., N₂, or forming gas and the terminating species includes nitrogen and hydrogen. In some embodiments, the surfaces may be activated using a wet cleaning process, e.g., by exposing the surfaces to aqueous solutions. In some embodiments, the aqueous solution is tetramethylammonium hydroxide diluted to a certain degree or percentage. In some embodiments, an aqueous solution may be ammonia. In some embodiments, the plasma is formed using a fluorine-containing gas, e.g., fluorine gas or helium containing a small amount of fluorine and/or nitrogen such as about 10% or less by volume, 9% or less, 8% or less, 7% or less, 6% or less, 5% or less, 4% or less, 3% or less, 2% or less, for example 1% or less.

Typically, the hybrid bonding methods further include aligning the substrates, and contacting the activated surfaces to form direct dielectric bonds. After the dielectric bonds are formed, the substrates may be heated to a temperature between 50° C. to 350° C. or more, or of 150° C. or more and maintained at the elevated temperature for a duration of about 1 hour or more, such as between 8 and 24 hours, to form direct metallurgical bonds between the metal features.

As used herein, the term “substrate” means and includes any workpiece, wafer, panel, or article that provides a base material or supporting surface from which or upon which components, elements, devices, assemblies, modules, systems, or features of the devices described herein may be formed. The term substrate also includes display substrates such as glass panels or “semiconductor substrates” that provide a supporting material upon which elements of a semiconductor device are fabricated or attached, and any material layers, features, electronic devices, and/or passive devices formed thereon, therein, or therethrough. For ease of description elements, features, and devices formed therefrom are referred to in the singular or plural but should be understood to describe both singular and plural, e.g., one or more, unless otherwise noted.

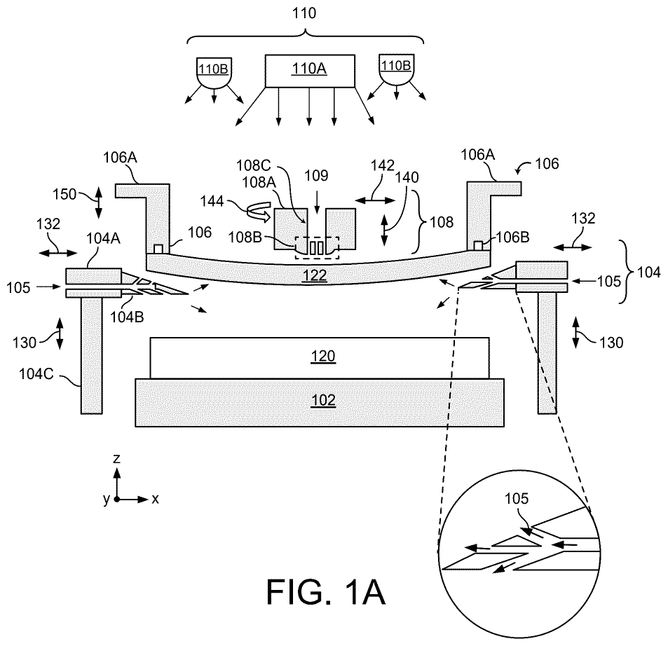

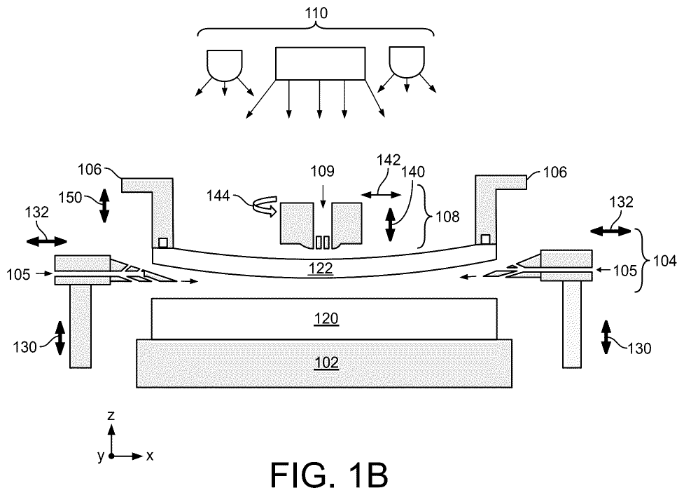

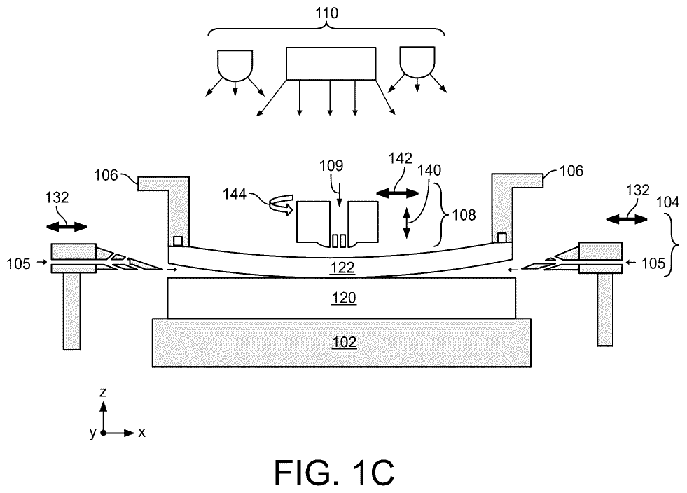

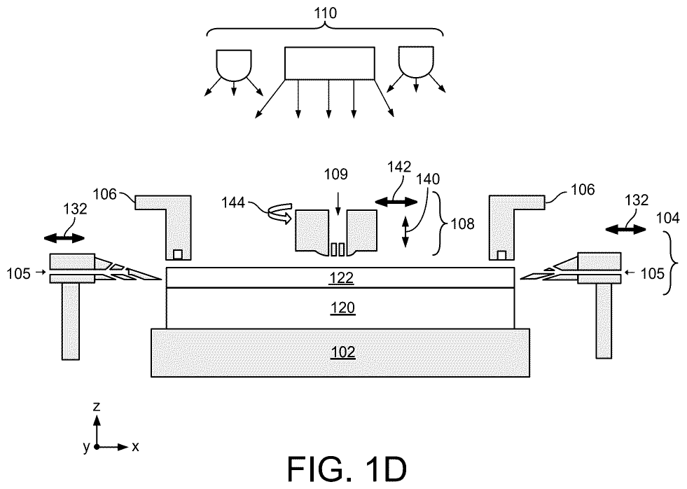

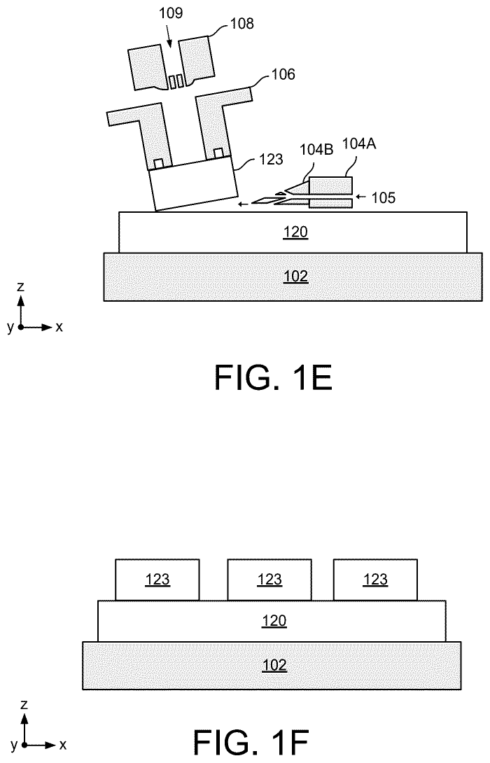

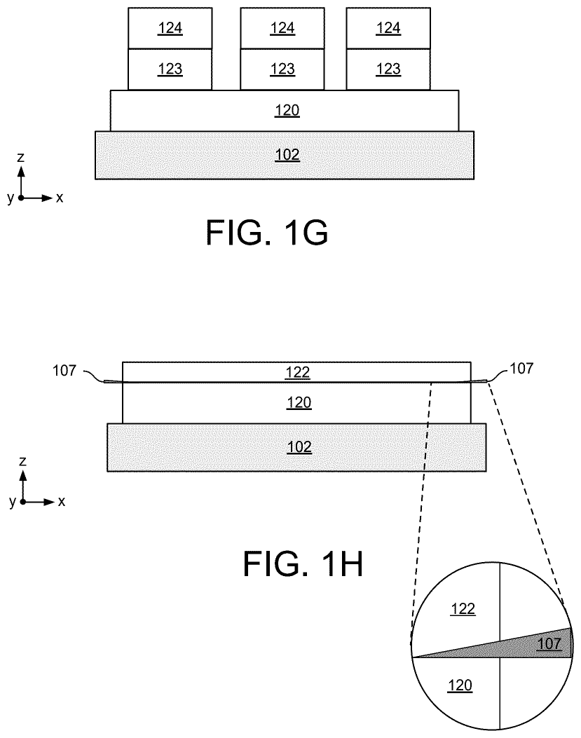

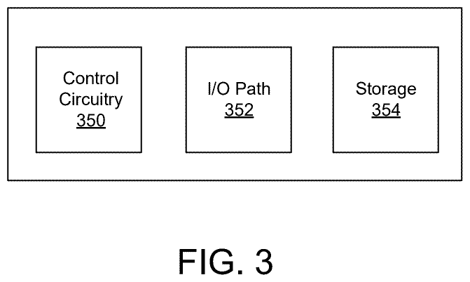

FIGS. 1A-1D are illustrative schematic sectional side views of a system at different stages of bonding substrates to illustrate aspects of a method to bond substrates, in accordance with some embodiments. The system may include a carrier device 102, a bonding wave front controller device 104, substrate handling device 106, a bonding initiating device 108, and a detector device 110 (e.g., infrared (IR) camera, detector, light scattering detector). The system may include a controller, an input/output (I/O) device, and storage (e.g., control circuitry 350, I/O path 352, storage 354 shown in FIG. 3). The controller may be communicatively coupled to (e.g., receive data from and/or provide instructions to) the devices (e.g., bonding initiating device 108, the bonding wave front controller device 104, and the detector device 110).

The carrier device 102 may be a plate or a chuck to hold a substrate 120 in place. A substrate 120 may be placed on the carrier device 102. In some embodiments, the carrier device 102 may have vacuum grooves to hold the substrate 120 in place when vacuum is pulled or drawn through the grooves (e.g., similar to grooves 106B as applied to carrier device 102). In some embodiments, the carrier device 102 may hold the substrate in place using any suitable technique (e.g., vacuum, electrostatic chuck, adaptor plate, clamps, etc.).

The bonding wave front controller device 104 provides air pressure (e.g., lateral, horizontal, etc.) against a bonding wavefront to control a bonding wavefront between substrates. The bonding wave front controller device 104 may control a rate at which a bonding wavefront propagates between substrates.

The bonding wave front controller device 104 may comprise a plurality pressure applicator portions. Each pressure applicator portion may comprise a body portion 104A and a corresponding tip portion 104B. Each body portion 104A may have one or more channels (shown as one channel). Each tip portion 104B may have multiple channels or nozzles (shown as three or four channels or nozzles). Although a specific number of channels or nozzles may be shown in FIGS. 1A-1D, any suitable number of channels or nozzles may be used (e.g., 1, 2, 3, 5, 10, 50, 300 or more) in any suitable configurations (e.g., similar or different body portion and corresponding tip portion among a plurality of body and corresponding tip portions in the bonding wavefront controller device). The bonding wave front controller device 104 may be movable (e.g., motorized), such that it has at least two degrees of freedom: in a vertical plane 130 (e.g., z direction or up/down) perpendicular to the second substrate 120, and in a horizontal plane (e.g., radially in towards or out from the center of the second substrate 120) parallel to the second substrate 120. In some embodiments, the bonding wave front controller device 104 may be movable (e.g., motorized) to include a tilting motion with respect to the horizontal plane (e.g., rotation along x or y axis).

Although the cross section shown in FIGS. 1A-1D shows two pressure applicator portions (e.g., two body portions 104A and two tip portions 104B), any suitable number of pressure applicator portions may be used (e.g., 1, 2, 3, 4 or more) in any suitable arrangement. In some embodiments, pressure applicator portions may be spaced at a radial distance from a center point of the first substrate 122 and/or the second substrate 120, and from each other. Each pressure applicator portion may have a corresponding motorized portion (e.g., motion controller device 104C). The motorized portion enables the pressure applicator portion to have vertical motion 130 along a z-axis and a horizontal motion 132 (e.g., radially away from the center point of the first substrate 122 and/or the second substrate 120, along an x axis, and/or y axis). For example, each pressure applicator portion may be mounted on a motion controller device 104C (e.g., XYZ motorized stage, etc.).

The substrate handling device 106 may be a holder that holds or handles a substrate 122. In some embodiments, substrate handling device may be an end effector. An end effector may be device or tool attached to a robot arm to handle a substrate. As shown, the substrate handling device 106 may be a cross section of a continuous ring (e.g., groove 106B) or any suitable shape used to hold the substrate 122. The substrate handling device 106 may comprise a body portion 106A and one or more grooves (shown as one groove 106B). A vacuum may be coupled (e.g., via tubing) to an opening (e.g., channel) in the body portion 106A that is connected to the groove 106B. The substrate handling device 106 may provide suction by pulling vacuum through the channels and the one or more grooves to hold a substrate 122 against a surface of the body portion 106A. In some embodiments, the substrate handling device 106 may further comprise a motorized portion (e.g., similar to motion controller device 104C as applied to substrate handling device 106) to move the substrate 122 in a vertical direction 150 and/or a horizontal directions (e.g., a Z motion controller, an XYZ motion controller, etc.).

The bonding initiating device 108 provides a pressure (e.g., in a vertical direction, downwards on the substrate 122) to bond at least a portion of the substrates. The bonding initiating device 108 may include a body portion 108A comprising a cavity volume 108C and an outlet portion 108B comprising channels. For example, the outlet portion comprises three channels or openings as shown in FIG. 1A, but any suitable number of channels or openings may be used (1, 2, 3 or more channels). The use of multiple channels may enable pressure to be distributed over a larger area than a single channel. The bonding initiating device 108 may apply downward pressure through the channels of the outlet portion 108B from a source (e.g., gas tank, nitrogen gas tank) coupled to the cavity volume 108C of the body portion 108A.

In some embodiments, the bonding initiating device 108 may be movable (e.g., be motorized) and may have at least four degrees of freedom of movement. For example, the bonding initiating device 108 may be enabled for horizontal movement 142 (e.g., x and y motion or front/back and left/right motion) parallel to the first substrate 122 and enabled for vertical movement 140 (e.g., z motion or up/down motion) perpendicular to the first substrate 122. The bonding initiating device 108 may be enabled for rotational movement 144 around the z axis perpendicular to the first substrate 122.

The detector device 110 enables detection of defects during bonding the substrates. In some embodiments, the detector device 110 comprises a light scattering detector or a detection device capable of detecting defects or unwanted particles between the first substrate 122 and the second substrate 120 or unwanted particle or particles on the second substrate 120. In some embodiments, the bonding wave profile may be imaged (e.g., monitored continuously or discretely) in situ (e.g., while the bonding process is in progress) by detector device 110. The detector device 110 may comprise one or more detectors (e.g., cameras, IR cameras) or any suitable number of detectors (e.g., 1, 2, 3 or more, etc.). The one or more detectors may capture images of the bonding wave profile. In some embodiments, the detector device 110 comprises a detector device 110A and one or more source devices 110B (shown as two devices). A source device 110B may be an infrared LED that emits light as indicated by the arrows from source device 110B. A detector device 110A may be an infrared detector that covers an area as shown by arrows from the detector device 110A. Light emitted by source devices 110B may reflect off surfaces (e.g., top and bottom surfaces of first substrate 122 and/or second substrate 120, an interface between bonded substrates, etc.) to be detected by the detector device 110A.

In some embodiments, a method may include picking up a first substrate 122 at a periphery of the substrate 122 by the substrate handling device 106 (e.g., end effector). The method may include turning on a vacuum to hold the substrate 122 to the substrate handling device 106. The method may include providing or placing a second substrate 120 (e.g., host substrate) on a carrier device 102 (e.g., wafer chuck). The method may include turning on a vacuum to hold the substrate 120 to the carrier device 102. The method may include disposing (e.g., placing, aligning, floating) the first substrate 122 over the second substrate 120.

In some embodiments, the substrate handling device 106 may lower a first surface of the first substrate 120 towards a first surface of the second substrate 122 to be separated by a distance (e.g., gap). The method may include instructing a motion controller to lower the first substrate 122 in a vertical direction 150 (e.g., Z direction) to a particular height. In some embodiments, the substrate 122 may be lowered using the bonding initiating device 108, the bonding wavefront controller device 104, or a combination thereof. The bonding initiating device 108 may lower or help lower at least a portion of the first substrate by applying a pressure 109 (e.g., via pressurized gas such as N₂, or any suitable gas) on a second surface of the first substrate 122 (e.g., backside or any suitable side of the substrate). The applicator portion 104B of the bonding wavefront controller device 104 may be positioned underneath or at the periphery of the substrate 122 and may apply an upwards or lateral pressure on the first substrate 122. A method of lowering the second substrate 122 may use a combination of controlling the downward and upward/lateral pressure on the substrate 122 to lower the substrate 122.

In some embodiments, at least one applicator portion 104B of the bonding wave front controller device 104 is positioned between the first substrate 122 and the second substrate 120, such that it can apply pressure 105 (e.g., via pressurized gas such as N₂ or any suitable gas) between the first substrate 122 and the second substrate 120. The application of pressure between the first substrate 122 and the second substrate 120 may help control the propagation of the bonding wave front when the first substrate 122 is lowered to contact the second substrate 120 during bonding.

At FIG. 1A, substrate handling device 106 (e.g., one or more end effectors) holds the first substrate 122 (e.g., via vacuum suction at the periphery of the first substrate). The substrate handling device 106 may position the first substrate 122 over the second substrate 120. The first substrate 122 may be positioned over the second substrate 120 by controlling the pressure 109 (e.g., downward pressure) applied from the bonding initiating device 108 and the pressure 105 (e.g., upward pressure) applied from the bonding wave front controller device 104. In some embodiments, the substrate handling device 106 may comprise one or more motorized portions to position the first substrate 122 over the second substrate 120 (e.g., horizontal and vertical motion). In some embodiments, a method may include positioning the first substrate 122 over the second substrate 120 by a first distance (e.g., gap) at FIG. 1A. The first substrate 122 may be supported by pressure 105 (e.g., N2 foil). A first surface of the first substrate 122 may be positioned directly opposite to and at a first distance from a surface of the second substrate 120.

At FIG. 1B, the first substrate 122 is lowered (e.g., vertical movement 140) towards the second substrate 120 and an applicator portion 104B of the bonding wave front controller device 104 is moved outwards (e.g., in a horizontal motion 132). The first substrate 122 may be lowered by increasing the pressure 109 (e.g., applied in a negative z direction or downwards on the first substrate 122) via pressurized gas from the bonding initiating device 108 and reducing the pressure 105 (applied in a positive z direction or upwards on the first substrate 122) via pressurized gas from the bonding wave front controller device 104. The bonding wave front controller device 104 may move further outward radially along the horizontal plane as the first substrate is lowered. Moving further outward radially may reduce the amount of pressure applied in an upwards direction on the first substrate 122. In some embodiments, the substrate handling device 106 may comprise one or more motorized portions to position the first substrate 122 over the second substrate 120 (e.g., horizontal and vertical motion) and lowering may be performed by moving the first substrate closer to the second substrate via a motorized stage. In some embodiments, the first substrate 122 may be positioned over the second substrate 120 by a second distance (e.g., gap) closer than the first distance at FIG. 1B. The first substrate 122 may be supported by pressure 105 (e.g., N2 foil).

At FIG. 1C, the first substrate 122 may be lowered further towards the second substrate by increasing the pressure 109 applied by the bonding initiating device 108 and reducing the pressure 105 applied by the bonding wave front controller device 104 until a contact is formed between the first substrate 122 and the second substrate 120. In some embodiments, the substrate handling device 106 may comprise one or more motorized portions to position the first substrate 122 over the second substrate 120 (e.g., horizontal and vertical motion) and lowering may be performed by moving the first substrate closer to the second substrate via a motorized stage. The bonding wave front controller device 104 move further outwards along the horizontal plane. A bonding wave may propagate outwards radially from the center of the first substrate 122. The bonding wave front controller device 104 applies a lateral pressure 105 opposite the direction of the bonding wave to control the bonding wave propagation (e.g., rate of bonding between the surfaces) and prevent void-formation between the substrates. The bonding wave front controller device 104 moves outwards along the horizontal plane to enable the propagation of the bonding wave and free up the space between the substrates 122 and 120 to bond. In some embodiments, the bonding wave propagation may be controlled by the bonding initiating device 108 (e.g., scanning bonding head) and the bonding wave front controller device 104 (e.g., motorized bonding wave front controller). In some embodiments, at least a size (e.g., lateral dimension) of the first substrate 122 (e.g., die) is smaller than a size of the second substrate 120, and multiple dies 122 can be directly bonded on and across the surface of the second substrate, using the methods disclosed in the present disclosure (e.g., as shown in FIG. 1F). In some embodiments, one or more additional dies may be bonded over the bonded first substrate 122 to form a stack of bonded dies (e.g., as shown in FIG. 1G).

In some embodiments, the first substrate 122 may be a rectangular substrate, and the substrate handling device may tilt slightly (e.g., less than about 30 degrees with respect to the bonding surface of the second substrate 120, as shown in FIG. 1E). Bonding wave may propagate outwards from the edge of the first substrate 122 closer the bonding surface of the second substrate 120 towards the second edge of the first substrate. The bonding wave front controller device 104 applies a lateral pressure 105 opposite the direction of the bonding wave to control the bonding wave propagation (e.g., rate of bonding between the surfaces) and prevent void-formation between the substrates. The bonding wave front controller device 104 moves outwards along the horizontal plane to enable the propagation of the bonding wave and free up the space between the substrates 122 and 120 to bond. In some embodiments, the bonding wave propagation may be controlled by the bonding initiating device 108 (e.g., scanning bonding head) and the bonding wave front controller device 104 (e.g., motorized bonding wave front controller). In some embodiments, as disclosed earlier, at least a size (e.g., lateral dimension) of the first substrate 122 (e.g., die) is smaller than a size of the second substrate 120, and multiple dies 122 can be directly bonded on and across the surface of the second substrate, using the method of this invention. In some other applications, one or more additional dies may be bonded over the bonded first substrate 122 to form a stack of bonded dies.

At FIG. 1D, the first substrate 122 is completely bonded to the second substrate. The method may increase or control the pressure 109 applied by the bonding initiating device 108 and reduce the pressure 105 applied by the bonding wave front controller device 104 and the motion of the bonding wave front controller device 104 (e.g., motorized bonding wave front controller) until the entire surface of the first substrate 122 is bonded to the second substrate 120. The method may distribute the pressure 109 applied by the bonding initiating device 108 over different areas of the substrate 122 (e.g., moving radially outwards, and around a center of the first substrate 122 towards the edges of the first substrate 122) until the entire substrate 122 is bonded to substrate 120. The applicator portion 104b of the bonding wave front controller device 104 moves completely out of the space between the two substrates 122 and 120 so that the two substrates 122 and 120 are bonded. The first substrate 122 may be released by the substrate handling device 106.

In some embodiments, the detector device 110 (e.g., infrared cameras) may detect defects or formation of defects (e.g., voids, particles, or misalignments) between the substrates 122 and 120 while bonding is in progress. By increasing/reducing the pressures 105 and 109, the first substrate 122 may be raised or lowered in situ and defect or the void or misalignment may be subsequently eliminated (e.g., reworked). The bonding wave front controller device 104 may increase the applied pressure 105, while the bonding wave front initiating device 108 may reduce the applied pressure 109 to debond certain bonded portions of the first substrate 122 where a defect is detected. Once that portion is debonded, the defect may be removed (e.g., particle is blown away by the applied pressure 105, misalignment or void is corrected) and the bonding process may be restarted.

In some embodiments, reducing pressure 109 may include moving the bonding initiating device 108 away from the first substrate 122 (e.g., upwards on the vertical plane 140). In some embodiments, reducing pressure 109 may include moving the bonding initiating device 108 inwards along horizontal plane 142 towards a previously bonded portion of the substrates 120 and 122 (e.g., radially towards a center of the first substrate 120). In some embodiments, reducing pressure 109 may include closing a valve in the bonding initiating device 108 to prevent the pressure 109 from being applied altogether. In some embodiments, reducing pressure 109 may include reducing a rate of release of gas (e.g., nitrogen).

In some embodiments, increasing pressure 105 may include moving the wave front controller device 104 inwards on the horizontal plane towards the previously bonded portion of the substrates 120 and 122 (e.g., radially towards a center of the first substrate 120). In some embodiments, increasing pressure 105 may include increasing the rate of release of the gas (e.g., nitrogen). In some embodiments, a combination of two or more of the methods described here may be used.

FIGS. 1E-1H schematically illustrate variations of bonding substrates, in accordance with embodiments of the present disclosure. The first substrate (e.g., die 123) may be smaller in size than the second substrate 120. In some embodiments, the second substrate 120 is at least 2 times larger than the first substrate (e.g., die 123), at least 4 times larger than the first substrate (e.g., die 123), or at least 10 times larger than the first substrate (e.g., die 123) prior to the bonding operation. In some embodiments, subsequent to the bonding of the first and second substrates, the second substrate may be singulated.

FIG. 1E shows a small substrate (e.g., die 123) being tilted during bonding. In some embodiments, the bonding initiating device 108, substrate handling device 106, and/or wave front controller device 104 may include a motion controller device (e.g., motorized stages) capable of tilting or rotation (e.g., around a Y axis). A body portion 104A of the wave front controller device 104 may be attached to a motorized stage 104C (e.g., as shown in FIG. 1A) by an arm in a horizontal direction (e.g., X, Y direction) such that applicator portion 104B of the wave front controller device may move across or clear the second substrate 120. Although the bonding initiating device 108 is shown above the substrate handling device 106 in FIG. 1E, in some embodiments the bonding initiating device 108 may be closer to a backside surface of die 123 (e.g., surface opposite the bonding surface of die 123 to substrate 120). For example, a bonding initiating device 108, substrate handling device 106, and/or die 123 may be sized so that the bonding initiating device 108 can be positioned between right and left arms of the substrate handling device 106 to distribute pressure 109 on portions of the die 123.

FIG. 1F shows a plurality of dies 123 (e.g., first substrates) that are smaller than a size of the second substrate 120 that are directly bonded (e.g., hybrid bonded) to the second substrate 120. Although three dies 123 are shown, any suitable number of dies (e.g., 1, 2, 3 or more, etc.) may be bonded to the second substate 120.

FIG. 1G shows dies 124 (e.g., third substrates) bonded over the bonded dies 123 (e.g., bonded first substrates to the second substrate 120) to form a stack of bonded dies (e.g., dies 124 and dies 123). Although three stacks of bonded dies are shown in FIG. 1G, there may be any suitable number of stacks of bonded dies (e.g., 1, 2, 3 or more, etc.)

FIG. 1H shows a blade 107 inserted between first substrate 122 and second substrate 120. In some embodiments, the blade 107 may be provided on a motion controller device (e.g., motorized stage). The blade 107 may be moved in or out laterally (e.g., horizontal direction, X, Y direction). For example, the blade 107 may be moved inwards to help initiate debonding, or the blade 107 may be moved outwards to enable bonding of substrates. Although two blades 107 are shown in FIG. 1H, any suitable number of blades may be used (e.g., 1, 2, 3, 4 or more blades, etc.). In some embodiments, the blade 107 may be positioned at a periphery of the substrates to be bonded and may separate a portion of the substrates to prevent bonding of a particular region of the substrates (e.g., edge regions of substrates 122 and 120 of FIG. 1H). In some embodiments, the blade 107 may be positioned at a periphery of a die to be bonded (e.g., edge region of die 123 to be bonded to substrate 102 of FIG. 1E). In some embodiments, a blade 107 may be positioned around a right edge of the die 123 in FIG. 1E an area to be bonded.

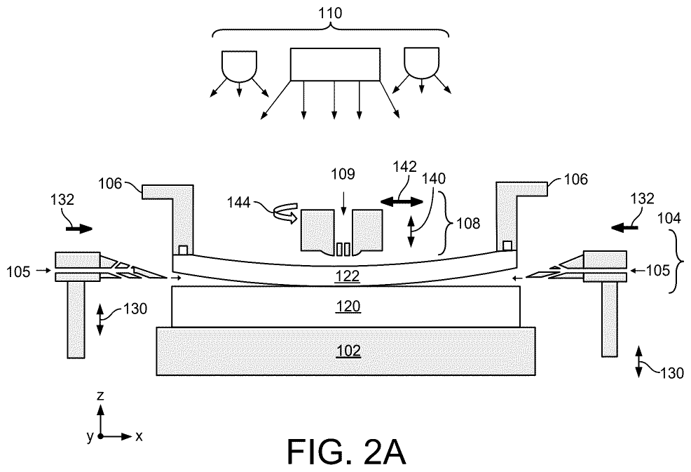

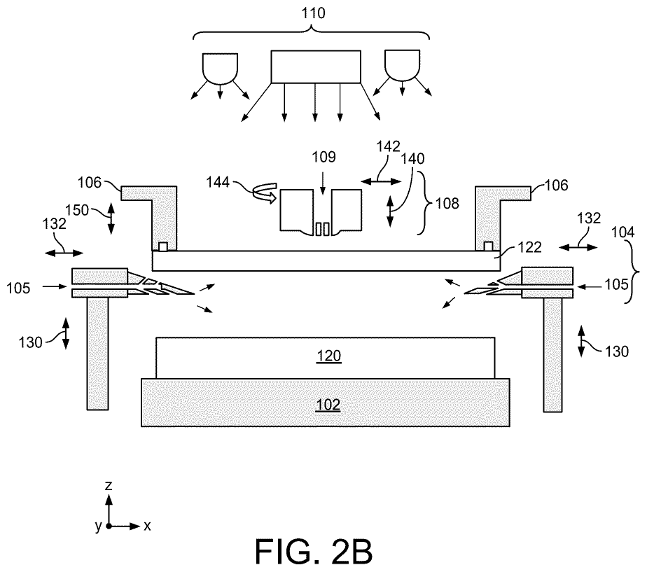

FIGS. 2A-2B are illustrative schematic sectional side views of a system at different stages of debonding substrates to illustrate aspects of a method to debond substrates, in accordance with some embodiments. In some embodiments, a first substrate 122 may be bonded to the second substrate 120 (e.g., as shown in FIG. 1D). In some embodiments, an apparatus or system used for bonding substrates (e.g., FIGS. 1A-1D) may be used for debonding devices (e.g., FIGS. 2A-2B). In some embodiments, the bonding initiating device 108 may apply pressure 109 (e.g., via N₂) on the backside of the first substrate 122 to help in controlling the debonding of the first substrate 122 from the second substrate 120. In some embodiments, the bonding initiating device may not apply a pressure while debonding substrates. In some embodiments, the debonding process may be imaged (e.g., monitored continuously or discretely) in situ (e.g., while the bonding process is in progress) by detector device 110 (e.g., infrared (IR) camera, detector). In some embodiments, a debonding apparatus or system may not include a bonding initiating device 108 and/or a detector device 110.

At FIG. 2A, the bonding wave front controller device 104 applies pressure 105 along the periphery of the bonded substrates 122 and 120, such that a gap is initiated between the substrates 122 and 120. In some embodiments, the gap may propagate at a bonding interface between the substrates 122 and 120 (e.g., exposed outermost edge of a bonding interface), In some embodiments, the gap may propagate from a weak location or a designed debonding location between the two bonded substrates 122 and 120. For example, in some embodiments, during the bonding operation one or more sharp blades (e.g., blade 107 as shown in FIG. 1H) may be inserted or disposed at the periphery between the substrates 120 and 122. And as depicted in FIG. 1C, the first substrate 122 may be lowered further towards the second substrate by increasing the pressure 109 applied by the bonding initiating device 108 and reducing the pressure 105 applied by the bonding wave front controller device 104 until a contact is formed between the first substrate 122 and the second substrate 120. The substrate handling device 106 may comprise one or more motorized portions to position the first substrate 122 over the second substrate 120 (e.g., horizontal and vertical motion) and lowering may be performed by moving the first substrate closer to the second substrate via a motorized stage. The bonding wave front controller device 104 may move further outwards along the horizontal plane. A bonding wave may propagate outwards radially from the center of the first substrate 122 towards the periphery of substrates 122 and 120, until it is intercepted by the one or more sharp blades disposed between substrates 122 and 120.

In some embodiments, the detector device 110 (e.g., infrared cameras) inspects for bonding defects between the bonded substrates. When the bonded substrates are free of unwanted defects, the one or more sharp blades are removed, and the bonding wave moves further outwards terminating close to or at the edge of the bonded substrates 122 and 120. In some cases, unwanted defects may be detected between the bonded substrates while bonding is in progress. The bonding wave front controller device 104 may increase the applied pressure 105, while the debonding wave front can be initiated at the locations of the one or more sharp blades disposed between substrates 122 and 120 to debond at least a portions of the bonded substrates or the entire bonded substrate 122 and 120. Once debonded, the defect may be removed (e.g., particle is blown away by the applied pressure 105, misalignment or void is corrected) and the bonding process may be restarted.

The bonding wave front controller device 104 moves inwards (e.g., radially towards a center of the second substrate) along the horizontal plane (e.g., horizontal motion 132) to control the debonding wave propagation and to perform or accelerate the debonding process. In some embodiments, the substrate handling device 106 holds the substrate to a body of the substrate handling device 106 via vacuum. In some embodiments, the bonding initiating device 108 may not provide a pressure 109. For example, a valve controlling pressure release or applying pressure (e.g., via N₂ gas) may be closed. In some embodiments, a motorized portion of the substrate handling device 106 may be used to raise the first substrate 122. In some embodiments, a second pressure 109 may be applied by the bonding initiating device 108 to control the raising of the first substrate 122 as it is debonded and to hold it in place. In some embodiments, a second pressure 109 may be applied to control a debonding wave propagation. In some embodiments, in situ wafer debonding of the substrate 122 from substrate 120 may be controlled by boding initiating device 108 (e.g., scanning bonding head) and a bonding wave front controller device 104 (e.g., motorized bonding wave front controller). In some embodiments, a method may comprise increasing N2 pressure (e.g., pressure 105) and forward motion (e.g., horizontal motion 132) of the bonding wave front controller device 104 to separate substrate 122 from substrate 120 (e.g., host).

At FIG. 2B, the applicator portion 104B of the bonding wave front controller device 104 may move inwards and apply a similar or same pressure. In some embodiments, the pressure 109 applied by the bonding initiating device 108 may be reduced simultaneously. The bonding initiating device 108 may reduce the pressure 109 applied and/or the bonding wave front controller device 104 may increase to the pressure to lift the first substrate 122 partially or wholly off the second substrate 120. In some embodiments, in situ rework (e.g., to remove defects) may be performed. In some embodiments, the bonding wave front controller device 104 may increase the pressure 105 between the partially separated substrates 122 and 120, as the gap between the substrates 122 and 120 becomes larger. In some embodiments, increasing an applied pressure may comprise increasing a pressure of pressurized gas used to apply the pressure. In some embodiments, pressure 109 may not be applied by the bonding initiating device 108. For example, a valve controlling pressure release or applying pressure (e.g., via N₂ gas) may be closed. In some embodiments, the substrate handling device 106 holds the substrate 122 via vacuum. A motorized portion of the substrate handling device 106 may be used to raise the first substrate 122 in a vertical direction 150. The substrates may debond completely. In some embodiments, the debonded substrates are supported with pressure 109 (e.g., N2 foil).

In some embodiments, a method for debonding bonded first and second substrates includes holding, via a substrate handling device 106, the bonded first and second substrates 122, 120 at a surface of the first substrate 122 via vacuum. The method may include applying a pressure via pressurized gas at the periphery of the bonded surfaces of the first and second substrates 122, 120 and in a direction parallel to the bonded surfaces of the substrates (e.g., lateral direction) to initiate debonding of the bonded substrates 122, 120. The method may include moving the bonding wave front controller 104 radially inwards towards a center of the first substrate 122 to apply the pressure to different portions of the bonded substrates 122, 120 to debond the bonded substrates.

FIG. 3 shows a computing device, in accordance with some embodiments. The computing device includes control circuitry 350, I/O path 352 or I/O circuitry, and storage 354 (e.g., RAM, ROM, Hard Disk, Removable Disk, etc.). The computing device may be communicatively coupled to the components of the system or apparatus (e.g., carrier device 102, bonding wave front controller device 104, substrate handling device 106, bonding wavefront initiating device 108, detector device 110) described in FIGS. 1A-1D and FIGS. 2A-2B. Control circuitry 350 may be a controller that provide instructions and/or receive data from the various devices through I/O path 352 and retrieve or store data in storage 354.

I/O path 352 may provide data, device information, or other data, over a local area network (LAN) or wide area network (WAN), and/or other content and data to control circuitry 350, which may include processing circuitry. Control circuitry 350 may be used to send and receive commands, requests, and other suitable data using I/O path 352 which may comprise I/O circuitry. I/O path 352 may connect control circuitry 350 to one or more communications paths.

Control circuitry 350 may be based on any suitable control circuitry such as one or more microprocessors, microcontrollers, digital signal processors, programmable logic devices, field-programmable gate arrays (FPGAs), application-specific integrated circuits (ASICs), etc., and may include a multi-core processor (e.g., dual-core, quad-core, hexa-core, or any suitable number of cores) or supercomputer. Memory may be an electronic storage device provided as storage 354 that is part of control circuitry 350.

In some embodiments, the first substrate 122 and/or the second substrate 120 may be large substrates. A large substrate may be a die greater than about 10 mm×10 mm in size. A large substrate may be about 300 mm in size or larger (e.g., 300 mm wafer, a wafer with a diameter that is about 300 mm or larger) or a flat panel (e.g., a flat panel with high die counts). In some embodiments, large substrates may be wafer to wafer (W2W) or panel to panel (P2P) bonded. In some embodiments, the bonding may be free of voids. In some embodiments, the first substrate 122 and/or the second substrate 120 may be any suitable size (e.g., less than or greater than about 10 mm, 100 mm, 200 mm, or 300 mm in size).

In some embodiments, the method may enable simultaneous in situ imaging and bonding. A bonding wave front controller device 104 may be capable of applying a second pressure 105 to control the bonding wave front while the detection device 110 captures an image of a bonding wave profile. A first applied downward gas pressure (e.g., pressure 109) may be applied over the substrate (e.g., first substrate 122) and a second gas pressure (e.g., pressure 105) may be applied about parallel and opposite to the direction of the propagation of the bonding wave. The method may enable in situ rework and/or void free bonding of large substrates.

In some embodiments, the method comprises an end effector (e.g., substrate handling device 106) picking a substrate (e.g., substrate 122) at a periphery of the substrate (e.g., wafer) and disposing the substrate over a host (e.g., host substrate, substrate 120). The substrate (e.g., substrate 122) may be floating over host (e.g., substrate 120) with aid of N2 foil or curtain (e.g., pressure 105). The method may include top downward scanning distributed N2 pressure (e.g., pressure 109, downward pressure) at center and distributed lifting pressure (e.g., pressure 105) between host (e.g., substrate 120) and wafer (e.g., substrate 122). The method may include bonding initiated with increasing top N2 pressure at wafer (e.g., substrate 122) center. The method may include scanning and rotating top N2 applied (e.g., pressure 109) to control propagation of bonding wave front. A motorized bonding wafer controller (e.g., bonding wave front controller device 104) may move outwards to control bonding wave propagation. The method may include simultaneous imaging of bonding wave profile (e.g., via detector device 110).

In some embodiments, the substrate (e.g., wafer, substrate 122) may be supported with N2 foil. In some embodiments, the substrate may be proximate to host (e.g., host substrate, substrate 120) and still supported by N2 foil. In some embodiments, the bonding wave propagation is controlled by a scanning bonding head (e.g., bonding initiating device 108) and/or a motorized bonding wave front controller (e.g., wave front controller device 104). In some embodiments, the bonding is initiated at wafer (e.g., substrate 122) center by increasing top N2 pressure and reducing the pressure from the bonding wave front controller. In some embodiments wafer bonding is performed by (1) increasing or controlling or controlled N2 pressure (e.g., pressure 109) in scanning bonding head (e.g, bonding initiating device 108) and scanning head motion and/or (2) reducing N2 pressure (e.g., pressure 105) from motorized bonding wave front controller (e.g., bonding wave front controller 104) and motion of the controller (e.g., bonding wave front controller 104). In some embodiments, in situ wafer debonding of substrate from host (e.g., substrate 120) is controlled by a scanning bonding head (e.g, bonding initiating device 108) and a motorized bonding wave front controller (e.g., bonding wave front controller 104). Increasing N2 pressure (e.g., pressure 105) and forward motion of bonding wafer controller (e.g., bonding wave front controller 104) may be used to separate substrate (e.g., substrate 122) from host (e.g., substrate 120). In some embodiments, wafer debonding method may include supporting a debonded substrate (e.g., substrate 122) with N2 foil.

In some embodiments, the method may enable controlled or fully controlled bonding wafer propagation. In some embodiments, a first gas pressure (e.g., perpendicular gas pressure, downward pressure) is applied over the substrate and a second gas pressure is applied about parallel and opposite to the direction of the propagation of the bonding wave. In some embodiments, N2 foils, air foils, or gas foils (e.g., foil using any suitable gas) enable a no contact process. In some embodiments, the method may enable in situ imaging during bonding operation. In some embodiments, the method may enable in situ rework if needed.

In some embodiments, one or more substrates (e.g., substrates 120, 122) may have a thickness of less than about 900 microns. In some embodiments, one or more wafers (e.g., substrates 120, 122) may have a thickness of less than about 600 microns. In some embodiments, one or more wafers (e.g., substrates 120, 122) may be about 25-50 microns thick, about 250-500 microns thick, or about 600-900 microns thick. In some embodiments, a deflection of a first substrate (e.g., due to applied pressure) between the substrates may be several hundred microns, about 100-200 microns, less than or over about 300 microns, less than or over about 400 microns. In some embodiments, a gap between a first substrate and a second substrate may be several hundred microns, about 100-200 microns, less than or over about 300 microns, less than or over about 400 microns.

In some embodiments, a rate of bonding may be controlled. In some embodiments, a rate of debonding the substrates may be controlled. In some embodiments, an initial contact point of the bonding may be a single point of contact as pressure may be applied from a bonding initiating device with a single opening and source of gas (e.g., N2). In some embodiments, an initial point of contact may be distributed as pressure may be applied from a bonding initiating device with multiple openings and source of gas (e.g., a source of N2 through several openings distributed over an area instead of a single opening).

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 408a and/or 408b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, and U.S. Patent Application No. 18/391, 173, filed Dec. 20, 2023, the entire contents of each of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

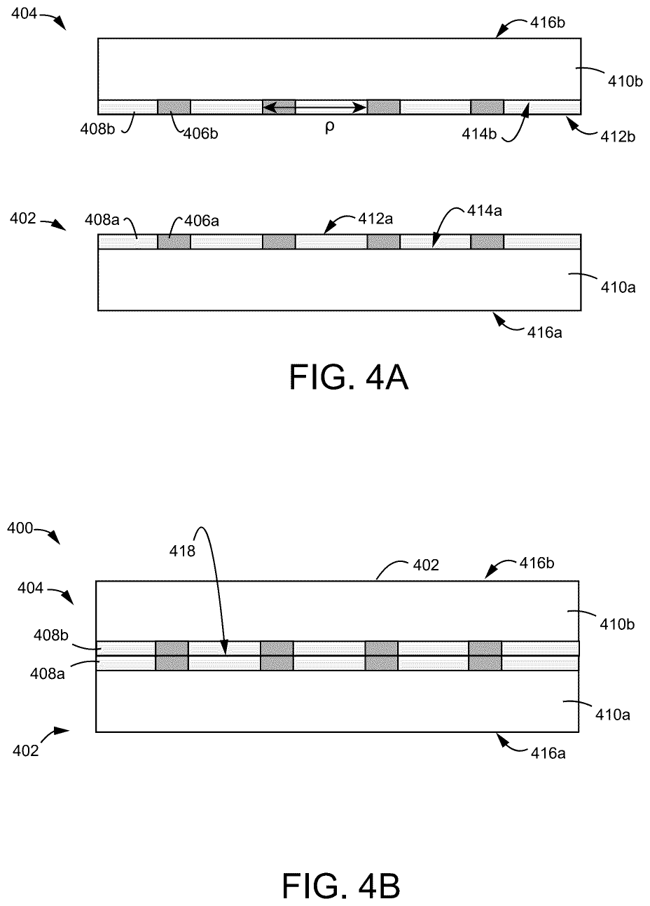

FIGS. 4A and 4B schematically illustrate cross-sectional side views of first and second elements 402, 404 prior to and after, respectively, a process for forming a directly bonded structure, and more particularly a hybrid bonded structure, according to some embodiments. In FIG. 4B, a bonded structure 400 comprises the first and second elements 402 and 404 that are directly bonded to one another at a bond interface 418 without an intervening adhesive. Conductive features 406a of a first element 402 may be electrically connected to corresponding conductive features 406b of a second element 404. In the illustrated hybrid bonded structure 400, the conductive features 406a are directly bonded to the corresponding conductive features 406b without intervening solder or conductive adhesive.

The conductive features 406a and 406b of the illustrated embodiment are embedded in, and can be considered part of, a first bonding layer 408a of the first element 402 and a second bonding layer 408b of the second element 404, respectively. Field regions of the bonding layers 408a, 408b extend between and partially or fully surround the conductive features 406a, 406b. The bonding layers 408a, 408b can comprise layers of non-conductive materials suitable for direct bonding, as described above, and the field regions are directly bonded to one another without an adhesive. The non-conductive bonding layers 408a, 408b can be disposed on respective front sides 414a, 414b of base substrate portions 410a, 410b.

The first and second elements 402, 404 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 402, 404, and back-end-of-line (BEOL) interconnect layers over such semiconductor portions. The bonding layers 408a, 408b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 410a, 410b, and can electrically communicate with at least some of the conductive features 406a, 406b. Active devices and/or circuitry can be disposed at or near the front sides 414a, 414b of the base substrate portions 410a, 410b, and/or at or near opposite backsides 416a, 416b of the base substrate portions 410a, 410b. In other embodiments, the base substrate portions 410a, 410b may not include active circuitry, but may instead comprise dummy substrates, passive interposers, passive optical elements (e.g., glass substrates, gratings, lenses), etc. The bonding layers 408a, 408b are shown as being provided on the front sides of the elements, but similar bonding layers can be additionally or alternatively provided on the back sides of the elements.

In some embodiments, the base substrate portions 410a, 410b can have significantly different coefficients of thermal expansion (CTEs), and bonding elements that include such different based substrate portions can form a heterogenous bonded structure. The CTE difference between the base substrate portions 410a and 410b, and particularly between bulk semiconductor (typically single crystal) portions of the base substrate portions 410a, 410b, can be greater than 5 ppm/° C. or greater than 10 ppm/° C. For example, the CTE difference between the base substrate portions 410a and 410b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 410a, 410b can comprise optoelectronic single crystal materials, including perovskite materials, that are useful for optical piezoelectric or pyroelectric applications, and the other of the base substrate portions 410a, 410b comprises a more conventional substrate material. For example, one of the base substrate portions 410a, 410b comprises lithium tantalate (LiTaO₃) or lithium niobate (LiNbO₃), and the other one of the base substrate portions 410a, 410b comprises silicon (Si), quartz, fused silica glass, sapphire, or a glass. In other embodiments, one of the base substrate portions 410a, 410b comprises a III-V single semiconductor material, such as gallium arsenide (GaAs) or gallium nitride (GaN), and the other one of the base substrate portions 410a, 410b can comprise a non-III-V semiconductor material, such as silicon (Si), or can comprise other materials with similar CTE, such as quartz, fused silica glass, sapphire, or a glass. In still other embodiments, one of the base substrate portions 410a, 410b comprises a semiconductor material and the other of the base substrate portions 410a, 410b comprises a packaging material, such as a glass, organic or ceramic substrate.

In some arrangements, the first element 402 can comprise a singulated element, such as a singulated integrated device die. In other arrangements, the first element 402 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 404 can comprise a singulated element, such as a singulated integrated device die. In other arrangements, the second element 404 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 402, 404 are shown, any suitable number of elements can be stacked in the bonded structure 400. For example, a third element (not shown) can be stacked on the second element 404, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 402. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 408a, 408b, the bonding layers 408a, 408b can be prepared for direct bonding. Non-conductive bonding surfaces 412a, 412b at the upper or exterior surfaces of the bonding layers 408a, 408b can be prepared for direct bonding by polishing, for example, by chemical mechanical polishing (CMP). The roughness of the polished bonding surfaces 412a, 412b can be less than 30 Å rms. For example, the roughness of the bonding surfaces 412a and 412b can be in a range of about 0.1 Å rms to 15 Å rms, 0.5 Å rms to 10 Å rms, or 1 Å rms to 5 Å rms. Polishing can also be tuned to leave the conductive features 406a, 406b recessed relative to the field regions of the bonding layers 408a, 408b.

Preparation for direct bonding can also include cleaning and exposing one or both of the bonding surfaces 412a, 412b to a plasma and/or etchants to activate at least one of the surfaces 412a, 412b. In some embodiments, one or both of the surfaces 412a, 412b can be terminated with a species after activation or during activation (e.g., during the plasma and/or etch processes). Without being limited by theory, in some embodiments, the activation process can be performed to break chemical bonds at the bonding surface(s) 412a, 412b, and the termination process can provide additional chemical species at the bonding surface(s) 412a, 412b that alters the chemical bond and/or improves the bonding energy during direct bonding. In some embodiments, the activation and termination are provided in the same step, e.g., a plasma to activate and terminate the surface(s) 412a, 412b. In other embodiments, one or both of the bonding surfaces 412a, 412b can be terminated in a separate treatment to provide the additional species for direct bonding. In various embodiments, the terminating species can comprise nitrogen. For example, in some embodiments, the bonding surface(s) 412a, 412b can be exposed to a nitrogen-containing plasma. Other terminating species can be suitable for improving bonding energy, depending upon the materials of the bonding surfaces 412a, 412b. Further, in some embodiments, the bonding surface(s) 412a, 412b can be exposed to fluorine. For example, there may be one or multiple fluorine concentration peaks at or near a bond interface 418 between the first and second elements 402, 404. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and U.S. Pat. No. 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 400, the bond interface 418 between two non-conductive materials (e.g., the bonding layers 408a, 408b) can comprise a very smooth interface with higher nitrogen (or other terminating species) content and/or fluorine concentration peaks at the bond interface 418. In some embodiments, the nitrogen and/or fluorine concentration peaks may be detected using various types of inspection techniques, such as SIMS techniques. The polished bonding surfaces 412a and 412b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 408a and 408b can be directly bonded to one another without an adhesive. In some embodiments, the elements 402, 404 are brought together at room temperature, without the need for application of a voltage, and without the need for application of external pressure or force beyond that used to initiate contact between the two elements 402, 404. Contact alone can cause direct bonding between the non-conductive surfaces of the bonding layers 408a, 408b (e.g., covalent dielectric bonding). Subsequent annealing of the bonded structure 400 can cause the conductive features 406a, 406b to directly bond.

In some embodiments, prior to direct bonding, the conductive features 406a, 406b are recessed relative to the surrounding field regions, such that a total gap between opposing contacts after dielectric bonding and prior to anneal is less than 15 nm, or less than 10 nm. Because the recess depths for the conductive features 406a and 406b can vary across each element, due to process variation, the noted gap can represent a maximum or an average gap between corresponding conductive features 406a, 406b of two joined elements (prior to anneal). Upon annealing, the conductive features 406a and 406b can expand and contact one another to form a metal-to-metal direct bond.

During annealing, the conductive features 406a, 406b (e.g., metallic material) can expand while the direct bonds between surrounding non-conductive materials of the bonding layers 408a, 408b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 406a, 406b can comprise discrete pads, contacts, electrodes, or traces at least partially embedded in the non-conductive field regions of the bonding layers 408a, 408b. In some embodiments, the conductive features 406a, 406b can comprise exposed contact surfaces of TSVs (e.g., through silicon vias).

As noted above, in some embodiments, in the elements 402, 404 of FIG. 1A prior to direct bonding, portions of the respective conductive features 406a and 406b can be recessed below the non-conductive bonding surfaces 412a and 412b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 406a, 406b or to average depths of the recesses relative to local non-conductive field regions. Even for an individual conductive feature 406a, 406b, the vertical recess can vary across the feature, and so can be measured at or near the lateral middle or center of the cavity in which a given conductive feature 406a, 406b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 406a, 406b across the direct bond interface 418 (e.g., small or fine pitches for regular arrays).

In some embodiments, a pitch p of the conductive features 406a, 406b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 406a and 406b to one of the lateral dimensions (e.g., a diameter) of the bonding pad is less than is less than 20, or less than 10, or less than 5, or less than 3 and sometimes desirably less than 2. In various embodiments, the conductive features 406a and 406b and/or traces can comprise copper or copper alloys, although other metals may be suitable, such as nickel, aluminum, or alloys thereof. The conductive features disclosed herein, such as the conductive features 406a and 406b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 402, 404, as shown, the orientations of one or more conductive features 406a, 406b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 406b in the bonding layer 408b (and/or at least one internal conductive feature, such as a BEOL feature) of the upper element 404 may be tapered or narrowed upwardly, away from the bonding surface 412b. By way of contrast, at least one conductive feature 406a in the bonding layer 408a (and/or at least one internal conductive feature, such as a BEOL feature) of the lower element 402 may be tapered or narrowed downwardly, away from the bonding surface 412a. Similarly, any bonding layers (not shown) on the backsides 416a, 416b of the elements 402, 404 may taper or narrow away from the backsides, with an opposite taper orientation relative to front side conductive features 406a, 406b of the same element.

As described above, in an anneal phase of hybrid bonding, the conductive features 406a, 406b can expand and contact one another to form a metal-to-metal direct bond. In some embodiments, the materials of the conductive features 406a, 406b of opposite elements 402, 404 can interdiffuse during the annealing process. In some embodiments, metal grains grow into each other across the bond interface 418. In some embodiments, the metal is or includes copper, which can have grains oriented along the 411 crystal plane for improved copper diffusion across the bond interface 418. In some embodiments, the conductive features 406a and 406b may include nanotwinned copper grain structure, which can aid in merging the conductive features during anneal. There is substantially no gap between the non-conductive bonding layers 408a and 408b at or near the bonded conductive features 406a and 406b. In some embodiments, a barrier layer may be provided under and/or laterally surrounding the conductive features 406a and 406b (e.g., which may include copper). In other embodiments, however, there may be no barrier layer under the conductive features 406a and 406b.

The embodiments discussed above are intended to be illustrative and not limiting. One skilled in the art would appreciate that individual aspects of the apparatuses, systems, and methods discussed herein may be omitted, modified, combined, and/or rearranged without departing from the scope of the disclosure.

1. A method comprising:
positioning a first surface of a first substrate directly opposite to and at a distance from a surface of a second substrate;
applying a first pressure over a first portion of a second surface of the first substrate via pressurized gas to contact a first portion of the first surface of the first substrate to a first portion of the first surface of the second substrate; and
applying a second pressure via pressurized gas in a direction opposite a propagation direction of a bonding wave front between the first substrate and the second substrate to control the bonding wave front.

2. The method of claim 1, further comprising:
applying the first pressure while moving radially outwards and around the first portion of the second surface of the first substrate; and
concurrently applying the second pressure while moving radially outwards from the first portion of the second surface of the first substrate.

3. The method of claim 1, further comprising:
detecting a defect in a bonded portion of the substrates using an infrared camera; and
reducing the applied first pressure and increasing the applied second pressure on a current position of a portion of the bonded wafers.

4. The method of claim 3, wherein reducing the applied first pressure comprises moving the applied first pressure away from the first substrate.

5. The method of claim 3, wherein reducing the applied first pressure comprises moving the applied first pressure inwards towards a previously bonded portion of the substrates.

6. The method of claim 1, wherein reducing the applied first pressure comprises closing a valve to prevent the first pressure from being applied.

7. The method of claim 3, wherein increasing the applied second pressure comprises moving the applied second pressure inwards towards a previously bonded portion of the substrates.

8. The method of claim 3, wherein:
the defect is a particle; and
the method further comprises maintaining or increasing the second pressure at a position of the defect to remove the particle from between the substrates.

9. The method of claim 1, wherein positioning the first surface of the first substrate directly opposite to and at the distance from the first surface of the second substrate comprises balancing the first pressure applied downward on top of the first substrate and the second pressure applied upwards on the bottom of the first substrate.

10. The method of claim 1, wherein positioning the first surface of the first substrate directly opposite to and at the distance from the first surface of the second substrate comprises lowering the first substrate to the second substrate by a motorized portion of the handling device.

11. The method of claim 1, wherein the first substrate and the second substrate are wafers or dies with size greater than about 10 mm in size.

12. The method of claim 1, wherein the first substrate and the second substrate are wafers about 100 mm or greater in diameter.

13. The method of claim 1, wherein the first substrate and the second substrate are wafers about 200 mm or greater in diameter.

14. The method of claim 1, wherein the first substrate and the second substrate are wafers about 300 mm or greater in diameter.

15. The method of claim 1, further comprising:
picking up the first substrate using an end effector; and
aligning the first substrate to the second substrate.

16. The method of claim 1, further comprising:
floating the first substrate over the second substrate by balancing the first pressure and the second pressure.

17. A method of debonding substrates, the method comprising:
applying vacuum on an outward facing surface of the bonded substrates;
applying pressurized gas at an edge of the bonded surfaces of the substrates and in a direction parallel to the bonded surfaces of the substrates to initiate debonding of the substrates; and
moving the pressurized gas towards a center of the bonded substrates to debond the substrates.

18. An apparatus comprising:
a substrate handling device comprising a holder, the substrate handling device capable of applying a vacuum to hold a first substrate against the holder;
a bonding initiating device comprising a first motorized stage and a first pressure chamber, the bonding initiating device capable of applying a first pressure to contact a first portion the first substrate to a first portion of a second substrate and moving the first pressure in both lateral and vertical directions; and
a bonding wave front controller device comprising a second motorized stage and a second pressure chamber, the bonding wave front controller device capable of applying a second pressure to control a bonding wave front between the first substrate and the second substrate and moving the second pressure in a lateral direction.

19. The apparatus of claim 18, further comprising a detection device comprising an infrared camera, the detection device capable of detecting defects between the first substrate and the second substrate.

20. The apparatus of claim 19, wherein the bonding wave front controller device is capable of applying the second pressure to control the bonding wave front while the detection device captures an image of a bonding wave profile.
